(19) United States
(12) Patent Application Publication
(10) Pub. No.: US 2026/0018457 A1
(43) Pub. Date: Jan. 15, 2026

(54) METHODS OF PROCESSING SEMICONDUCTOR-ON-INSULATOR STRUCTURES USING CLEAN-AND-ETCH OPERATION

(71) Applicant: GlobalWafers Co., Ltd., Hsinchu (TW)

(72) Inventors: Qingmin Liu, Glen Carbon, IL (US); Henry F. Erk, St. Louis, MO (US); Haihe Liang, St. Peters, MO (US); Jeffrey L. Libbert, O'Fallon, MO (US); Xiaofei Lu, Chesterfield, MO (US); Charles R. Lottes, Ballwin, MO (US)

(21) Appl. No.: 19/264,197

(22) Filed: Jul. 9, 2025

Related U.S. Application Data
(60) Provisional application No. 63/669,488, filed on Jul. 10, 2024.

(51) Int. Cl. H01L 21/762; H01L 21/306

(52) U.S. Cl. CPC H01L 21/76259; H01L 21/30604

(57) ABSTRACT

A method of preparing a semiconductor-on-insulator structure from a bonded structure including a handle substrate, a donor substrate including a cleave plane, and a dielectric layer positioned between the handle substrate and the donor substrate, the method includes cleaving the bonded structure at the cleave plane to form a cleaved structure including the handle substrate, the dielectric layer, and a device layer. The single crystal semiconductor device layer defines a damaged region at an exposed surface opposite the dielectric layer. The damaged region includes single crystal semiconductor material and extends a thickness from the exposed surface. The method also includes removing the damaged region from the cleaved structure using a clean-and-etch operation that includes contacting the exposed surface of the device layer with an alkaline solution at a temperature and for a duration sufficient to remove the damaged region and smoothing the device layer with the damaged region removed.

### CROSS-REFERENCE TO RELATED APPLICATIONS

This application claims the benefit of priority to U.S. Provisional Patent Application No. 63/669,448, filed Jul. 10, 2024, the disclosure of which is incorporated herein by reference in its entirety.

### FIELD

The present disclosure relates generally to the manufacture of semiconductor-on-insulator (e.g., silicon-on-insulator) structures, and more particularly, to methods of preparing semiconductor-on-insulator structures that include a cleaving a donor substrate to transfer a semiconductor layer onto a handle substrate and a clean-and-etch operation performed on the transferred semiconductor layer.

### BACKGROUND

Single crystal silicon, which is a starting material for the fabrication of semiconductor electronic devices (e.g., microelectronic devices), is commonly prepared by growing a single crystal silicon ingot by the Czochralski (“CZ”) method. In this method, polycrystalline silicon is charged to a crucible and melted, a seed crystal is brought into contact with the molten silicon, and a single crystal ingot is grown by slow extraction. Other single crystal growth techniques, such as the float zone method, may also be utilized to produce single crystal silicon ingots. The single crystal silicon ingot is trimmed and ground to have one or more flats or notches for proper crystal orientation in subsequent procedures, and is then sliced into individual single crystal silicon wafers.

Silicon wafers may be utilized in the preparation of layered silicon-insulator-semiconductor structures, also referred to as silicon-on-insulator (SOI) structures, that facilitate reducing parasitic capacitance and improving performance of the end device. An SOI structure includes a semiconductor handle wafer, a device layer, and an insulator or dielectric layer (e.g., an oxide layer) between the handle wafer and the device layer. The device layer is typically a thin layer of single crystal silicon. The semiconductor handle wafer may be made of single crystal silicon, or other suitable semiconductor materials, such as germanium, silicon carbide, silicon germanium, gallium arsenide, and other alloys of Group III and Group V elements, such as gallium nitride or indium phosphide, or alloys of Group II and Group VI elements, such as cadmium sulfide or zinc oxide.

An SOI structure may be prepared by forming a dielectric layer (e.g., an oxide layer) on a polished front surface of a donor wafer made of single crystal silicon. Particles (e.g., hydrogen ions or a combination of hydrogen and helium ions) are implanted at a specified depth beneath the front surface of the donor wafer and form a cleave plane in the donor wafer at the specified implant depth. The front surface of the donor wafer is then bonded to a handle wafer to form a bonded structure through a hydrophilic bonding process. The handle wafer may additionally or alternatively include the dielectric layer. The donor wafer is thereafter separated (i.e., cleaved) along the cleave plane from the bonded structure to form the SOI structure. The resulting SOI structure includes a thin layer of silicon (the portion of the donor wafer remaining after cleaving) disposed atop the dielectric layer and the handle wafer. The thin layer of silicon forms the device layer of the SOI structure.

The cleaved surface of the thin layer of silicon typically has a rough surface that is ill-suited for end-use applications. The rough surface may be the result of the particle implantation and cleave, which may create dislocations in the crystal structure of the silicon. The cleaved surface also has many dangling bonds that make the cleaved surface relatively reactive and susceptible to attracting particles and contaminants from the surrounding environment to the surface. Typical SOI processes include a post-cleave standard cleaning operation (i.e., an SC1/SC2 clean) that is performed to remove the particles and contaminants and passivate the surface. Additional processing is also typically performed to smooth the cleaved surface. Known methods used to smooth and thin the surface layer of silicon include thermal annealing, chemical mechanical polishing, and combinations thereof. These smoothing processes may provide less than optimal surface roughness and/or thickness uniformities. If the post-cleave smoothing operations fail to achieve the SOI structure having the requisite surface roughness and/or thickness uniformity, the SOI structure is either scrapped, resulting in unacceptable yield loss, or additional processing must be performed on the SOI structure, increasing manufacturing and labor costs.

Accordingly, there is an ongoing need for efficient and cost-effective SOI processing methods that enable the production of SOI structures having acceptable surface roughness and thickness uniformity.

### BRIEF SUMMARY

One aspect is a method of preparing a semiconductor-on-insulator structure from a bonded structure including a single crystal semiconductor handle substrate, a single crystal semiconductor donor substrate, and a dielectric layer positioned between the handle substrate and the donor substrate, the single crystal semiconductor donor substrate including a cleave plane. The method includes: cleaving the bonded structure at the cleave plane to remove a portion of the single crystal semiconductor donor substrate from the bonded structure, thereby forming a cleaved structure comprising the single crystal semiconductor handle substrate, the dielectric layer, and a single crystal semiconductor device layer, wherein the single crystal semiconductor device layer defines a damaged region at an exposed surface opposite the dielectric layer, wherein the damaged region includes single crystal semiconductor material and extends a thickness from the exposed surface; removing the damaged region from the single crystal semiconductor device layer of the cleaved structure using a clean-and-etch operation that includes contacting the exposed surface of the single crystal semiconductor device layer with an alkaline solution at a temperature and for a duration sufficient to remove the damaged region; and smoothing the single crystal semiconductor device layer with the damaged region removed.

In some embodiments of the foregoing aspect, the alkaline solution is an alkali-oxide including at least one oxidizing agent and at least one alkaline agent.

In some embodiments of the foregoing aspect, the at least one alkaline agent is selected from the group consisting of ammonium hydroxide (NH₄OH), other amines such as di-, tri-, and tetra-amines (e.g., tetramethylammonium hydroxide (TMAH)), alkali metal hydroxides (e.g., NaOH, KOH, LiOH, Ca(OH)₂, Mg(OH)₂), organic hydroxides, and inorganic hydroxides.

In some embodiments of the foregoing aspect, the at least one oxidizing agent is selected from the group consisting of hydrogen peroxide (H₂O₂) and an aqueous ozone (O₃) solution. In some embodiments of the foregoing aspect, the at least one oxidizing agent is any other oxidizing agent which is effective at an elevated pH and is not rendered ineffective at a high pH.

In some embodiments of the foregoing aspect, the alkali-oxide includes the at least one alkaline agent, the at least one oxidizing agent, and deionized water in a concentration ratio (by volume) between 1:1:5 to 1:10:250, such as between 1:1:100 to 1:10:175, or 1:7:130 (alkaline agent:oxidizing agent:deionized water).

In some embodiments of the foregoing aspect, the at least one oxidizing agent is UHP hydrogen peroxide (30-32 wt. %) and the at least one alkaline agent is UHP ammonium hydroxide (28-30 wt. %).

In some embodiments of the foregoing aspect, the clean-and-etch operation includes contacting the exposed surface of the single crystal semiconductor device layer with the alkaline solution at a temperature of at least 40° C., or at least 55° C., or at least 65° C., such as between 55° C. to 85° C., between 65° C. to 85° C., between 70° C. to 80° C., or about 75° C.

In some embodiments of the foregoing aspect, the clean-and-etch operation includes contacting the exposed surface of the single crystal semiconductor device layer with the alkaline solution at the temperature and for a duration of less than two hours.

In some embodiments of the foregoing aspect, the duration is between five minutes to two hours, such as between 5 minutes to one hour, or between 5 minutes to 50 minutes.

In some embodiments of the foregoing aspect, the clean-and-etch operation further includes oxidizing the exposed surface of the single crystal semiconductor device layer prior to contacting the exposed surface with the alkaline solution.

In some embodiments of the foregoing aspect, oxidizing the exposed surface includes contacting the exposed surface with an aqueous ozone (O₃) solution.

In some embodiments of the foregoing aspect, the aqueous ozone solution includes ozone in a concentration of between 0.1 parts per million by weight (ppmw) to 90 ppmw, such as between 15 ppmw to 90 ppmw, or about 20 ppmw.

In some embodiments of the foregoing aspect, oxidizing the exposed surface is performed for a duration of at least 10 seconds, such as between 10 seconds to one hour, between 1 minute to 10 minutes, or about two minutes.

In some embodiments of the foregoing aspect, the clean-and-etch operation further includes contacting the exposed surface of the single crystal semiconductor device layer with an aqueous solution configured to remove surface metals from the exposed surface after contacting the exposed surface with the alkaline solution and removing the damaged region.

In some embodiments of the foregoing aspect, the aqueous solution configured to remove surface metals from the exposed surface does not substantially remove any of the single crystal semiconductor material from the single crystal semiconductor device layer.

In some embodiments of the foregoing aspect, the aqueous solution configured to remove surface metals from the exposed surface is one of an acid-oxide solution or carbon dioxide dissolved in deionized water.

In some embodiments of the foregoing aspect, the aqueous solution configured to remove surface metals from the exposed surface includes an oxidizing acid (e.g., HCl, HNO₃, H₂SO₄, etc.) or an acid-oxide solution including deionized water, at least one acid, and at least one oxidizing agent.

In some embodiments of the foregoing aspect, the oxidizing acid is hydrogen chloride (HCl), and the aqueous solution configured to remove surface metals from the exposed surface is free of oxidizing agents.

In some embodiments of the foregoing aspect, the at least one acid is selected from the group consisting of hydrogen chloride (HCl) and hydrogen fluoride (HF).

In some embodiments of the foregoing aspect, the at least one oxidizing agent is selected from the group consisting of hydrogen peroxide (H₂O₂) and an aqueous ozone (O₃) solution.

In some embodiments of the foregoing aspect, the aqueous solution configured to remove surface metals from the exposed surface includes the at least one acid, the at least one oxidizing agent, and deionized water in a concentration ratio (by volume) between 1:0:50 to 1:5:250, such as between 1:0:75 to 1:4:150, or 1:0:100 (acid:oxidizing agent:deionized water).

In some embodiments of the foregoing aspect, the at least one oxidizing agent is UHP hydrogen peroxide (30-32 wt. %) and the at least one acid is UHP hydrogen chloride (35-37 wt. %).

In some embodiments of the foregoing aspect, the clean-and-etch operation includes contacting the exposed surface of the single crystal semiconductor device layer with the aqueous solution configured to remove surface metals from the exposed surface at a temperature of at least 40° C., or at least 55° C., such as between 40° C. to 80° C., between 55° C. to 65° C., or about 60° C.

In some embodiments of the foregoing aspect, the clean-and-etch operation includes contacting the exposed surface of the single crystal semiconductor device layer with the aqueous solution configured to remove surface metals from the exposed surface at the temperature and for a duration of less than five minutes.

In some embodiments of the foregoing aspect, the duration is between thirty seconds to five minutes, such as between one minute to two minutes, or about 90 seconds.

In some embodiments of the foregoing aspect, contacting the exposed surface of the single crystal semiconductor device layer with the alkaline solution is performed in an agitating bath.

In some embodiments of the foregoing aspect, the damaged region has a thickness of at least 10 Angstroms, at least 30 Angstroms, at least 50 Angstroms, or at least 100 Angstroms.

In some embodiments of the foregoing aspect, the damaged region has the thickness of between 30 Angstroms to 300 Angstroms, between 30 Angstroms to 200 Angstroms, between 100 Angstroms to 200 Angstroms, or between 150 Angstroms to 200 Angstroms.

In some embodiments of the foregoing aspect, the single crystal semiconductor donor substrate is a single crystal silicon wafer.

In some embodiments of the foregoing aspect, the cleave plane is formed in the single crystal semiconductor donor substrate by implanting particles into the donor substrate.

In some embodiments of the foregoing aspect, cleaving the bonded structure at the cleave plane comprises mechanical cleaving.

In some embodiments of the foregoing aspect, smoothing the single crystal semiconductor device layer includes at least one of thermal annealing and epitaxial smoothing, and no additional smoothing operation is performed on the single crystal semiconductor device layer.

Advantages and features of the embodiments disclosed herein will be in part apparent and in part pointed out hereinafter.

### BRIEF DESCRIPTION OF THE DRAWINGS

FIG. 1 depicts a semiconductor-on-insulator (SOI) structure, according to embodiments of the present disclosure.

FIG. 2 is an example semiconductor structure used as a handle and/or donor substrate to prepare the SOI structure of FIG. 1.

FIG. 3 depicts one example of a process sequence for preparing the SOI structure of FIG. 1.

FIG. 4 is an atomic force microscopy image of a top surface of an SOI structure showing pit shape defects after thermal smoothing in pure argon ambient.

FIG. 5 is an atomic force microscopy image of a top surface of an SOI structure showing bump type defects after epitaxial smoothing.

Corresponding reference numerals are used throughout the drawings to indicate corresponding features and elements.

### DETAILED DESCRIPTION

Embodiments of the present disclosure relate to methods of manufacturing semiconductor-on-insulator (SOI) structures to reduce surface roughness and defectivity of a device layer of the SOI structure following a cleave operation. The SOI structure is manufactured by bonding a donor wafer or substrate (e.g., a single crystal semiconductor donor substrate, such as a single crystal silicon donor substrate) to a handle wafer or substrate (e.g., a single crystal semiconductor handle substrate, such as a single crystal silicon handle substrate) to form a bonded structure. One or both of the donor substrate and the handle substrate includes a dielectric layer (e.g., an oxide film) that defines a bonding surface of the substrate(s). The donor substrate includes a cleave plane formed, for example, by implanting hydrogen and/or helium ions or particles through a surface of the donor substrate. The bonded structure then goes through bond treatment (e.g., bond strengthening anneal) and cleaving (e.g., mechanical cleaving) at the cleave plane. Cleaving removes a portion of the donor substrate and forms a cleaved SOI structure including the handle structure, the dielectric layer(s), and a device layer (e.g., single crystal silicon film) on the dielectric layer(s). The device layer of the cleaved SOI structure has a relatively rough outer surface with many dangling bonds that make the surface quite reactive to attract particles and contaminants from the environment. In addition, due to the nature of the cleaving process (e.g., room-temperature, mechanical), there may be sub-surface damage in the device layer. The sub-surface damage, ideally, needs to be removed prior to subsequent (e.g., thermal) processing to prevent surface roughening or damage propagation further into the device layer. A standard SC1/SC2 clean is typically used to clean the wafer before the wafer undergoes smoothing and/or high temperature anneal processes to form the final SOI wafers. Industry standard SC1 temperature is often in the range of 55° C. to 65° C. for best overall performance.

Some SOI structures are subjected to post-cleave, thermal smoothing techniques in an attempt to smooth the top device layer surface. Examples of thermal smoothing techniques for SOI structures are described in U.S. Pat. No. 10,529,616, issued on Jan. 7, 2024, the disclosure of which is incorporated by reference in its entirety. Two types of thermal smoothing can be performed. One type is to anneal the cleaved SOI structure in a vertical furnace in pure (100%) argon, Ar, ambient at high temperature (>1,000° C.). This first type is also referred to as Ar smoothing. The other type is to place the SOI structure in an epitaxial reactor to smooth the surface using HCl etching at high temperature (>1,000° C.). This second type is also referred to as epitaxial smoothing or epi-smoothing. A semiconductor (e.g., silicon) epitaxial layer can also be grown on the top device layer following the epi-smoothing to thicken the device layer. Example epi-smoothing processes are described, for example, in U.S. Pat. No. 9,202,711, issued Dec. 1, 2015, the disclosure of which is incorporated by reference in its entirety. Either Ar smoothing or epi-smoothing, or a combination thereof, can be performed to smooth the SOI structure.

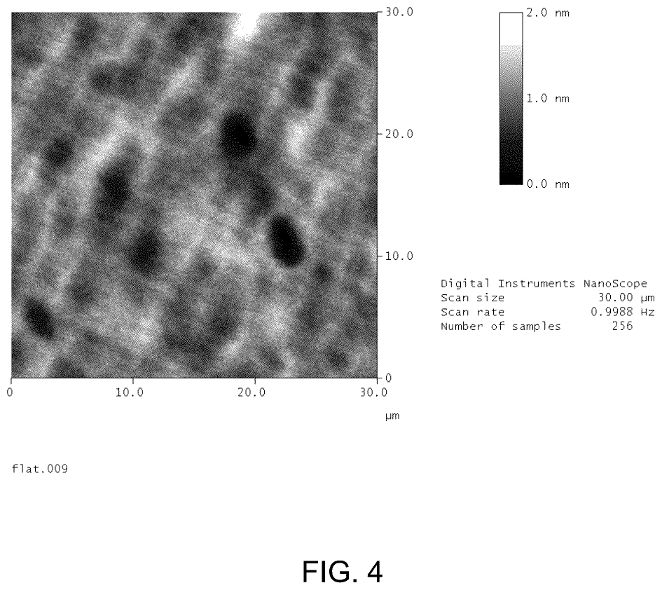

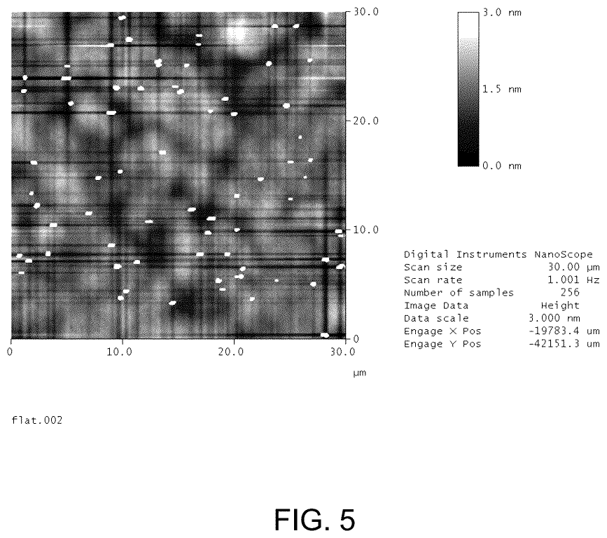

Referring to FIGS. 4 and 5, it has been discovered that pit shape defects or bump type defects can result from the thermal smoothing process(es) performed on the SOI structure, when a conventional SC1/SC2 clean is performed following cleave and prior to smoothing. These defects degrade the surface roughness of the final SOI structure. FIG. 4 is an atomic force microscopy (AFM) image that depicts pit shape defects that have been discovered after Ar smoothing. FIG. 5 is an AFM image that depicts bump type defects that have been discovered after epi-smoothing and growing an epitaxial silicon layer on the smoothed SOI surface. The bump type defects also degrade the surface roughness of the final SOI structure.

Without being bound by a particular theory, it is believed that the surface defects (pit shape or bump type defects) that form during the thermal smoothing process are consequence of imperfections (e.g., damages, particles, metal contaminants, etc.) on the post-cleave surface of the SOI device layer. The imperfections can cause the pit or bump defects in the following thermal smoothing step (e.g., Ar smoothing or epi-smoothing). Other attempts to remove the imperfections include layer thinning by sacrificial oxidation/deoxidation processes that are performed after the SC1/SC2 clean. For example, a thin silicon oxide layer is grown on the SOI structure in a vertical furnace (e.g., with steam via wet oxidation), and then strip the silicon oxide layer in diluted hydrogen fluoride (HF) solution. Alternatively, an oxide layer can be grown on the SOI structure by annealing the SOI structure in a vertical furnace in a nitrogen gas (N₂) and oxygen gas (O₂) environment, followed by stripping the oxide in diluted HF solution. These examples include the use of high temperature thermal process with either steam or N₂+O₂ gases to “lock” the imperfections in a thin oxide layer and then strip off this thin oxide layer in diluted HF solution. The SOI structure then goes to thermal smoothing step (Ar smoothing or epi-smoothing) with fewer imperfections to reduce or eliminate pit or bump defects during the thermal smoothing process. One disadvantage of the sacrificial oxidation/deoxidation processes is that it requires additional thermal oxidation/anneal and HF strip processes between the SC1/SC2 clean and the thermal smoothing step, thereby increasing the overall manufacturing cycle time and cost and making the SOI manufacturing process inefficient.

Methods according to the present disclosure include preparing SOI structures using a clean-and-etch operation that removes imperfections from the top device layer of the SOI structure during the cleaning step. This eliminates the need to perform an additional layer thinning step between the clean and thermal smoothing operation, while at the same time reducing or eliminating the risk of pit or bump defects in the SOI top surface following thermal smoothing. Since no additional layer thinning step is needed after the clean-and-etch, the SOI manufacturing process cycle time and cost are reduced and the process is more efficient. In some examples, the clean-and-etch operation includes a higher temperature SC1 clean in combination with an SC2 clean to improve the efficiency or effectiveness of cleaning off the imperfections. The high temperature SC1 removes contaminants (organic or inorganic) from the top surface of the device layer and also etches a thickness of the device layer to remove a damaged region and sub-surface damage from the device layer. For example, a thickness of the device layer that is removed during the high temperature SC1 clean can be at least 10 Angstroms, at least 30 Angstroms, at least 50 Angstroms, or at least 100 Angstroms, such as between 30 Angstroms to 300 Angstroms, between 30 Angstroms to 200 Angstroms, between 100 Angstroms to 200 Angstroms, or between 150 Angstroms to 200 Angstroms. The SC2 clean is then performed to remove any metal impurities or contaminants introduced during the SC1 clean. With the high temperature SC1 clean process, no additional process is needed between the clean and thermal smoothing processes. Thus, thermal smoothing (e.g., thermal annealing (Ar smoothing) or epi-smoothing) can be performed after the clean-and-etch operation. Since pit and bump defects are reduced or eliminated, no additional smoothing other than thermal smoothing may be needed. For example, chemical mechanical polishing may be avoided using the methods described herein.

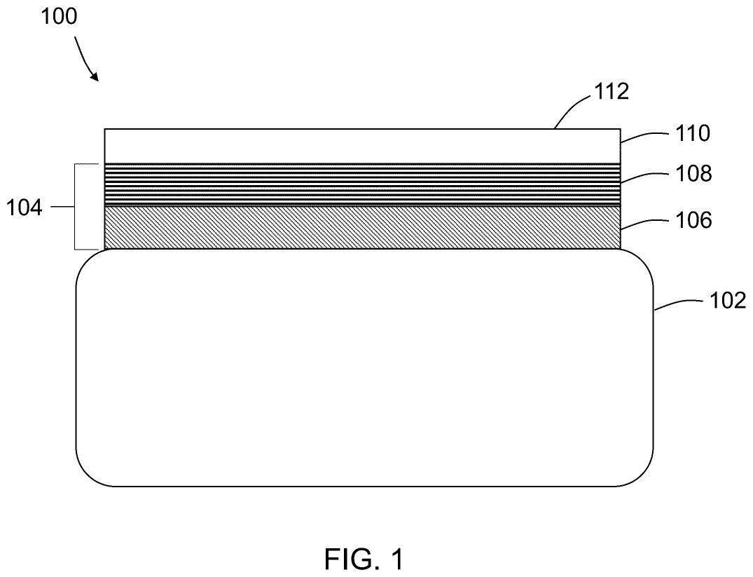

Referring now to the drawings, FIG. 1 depicts a multilayer structure 100 prepared according to embodiments of the present disclosure. The multilayer structure 100 is also referred to as a semiconductor-on-insulator structure 100 and, in some embodiments, is a silicon-on-insulator structure. The multilayer structure 100 includes, in stacked succession, a single crystal semiconductor handle substrate 102, an intermediate layer or layers 104, and a device layer 110. The intermediate layer 104 can include one or more dielectric layers 108 (also referred to as an insulating or insulator layer 108, or a buried oxide or BOX layer 108). In some embodiments, the intermediate layer 104 can also include a charge trapping layer 106 between the dielectric layer (s) 108 and the handle substrate 102.

The handle substrate 102 is made of any suitable semiconductor material. In some embodiments, the handle substrate 102 is made of single crystal silicon. In some embodiments, the handle substrate 102 is a single crystal silicon wafer. In various embodiments, the handle substrate 102 is made of a semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof.

The dielectric layer(s) 108 acts as an electrical insulator layer between the device layer 110 and the handle substrate 102 to minimize or eliminate leakage currents, lower parasitic capacitance, and otherwise improve the performance of the end device. The material used for the dielectric layer 108 varies depending on the intended application of the SOI structure 100 and/or the desired characteristics of the dielectric layer 108. In some embodiments, the dielectric layer 108 includes an oxide and/or a nitride film. In some embodiments, the dielectric layer 108 is in part or in whole a silicon dioxide (SiO₂) film. In various embodiments, the dielectric layer 108 includes a material selected from a group consisting of silicon dioxide, silicon nitride, silicon oxynitride, hafnium oxide, titanium oxide, zirconium oxide, lanthanum oxide, barium oxide, aluminum oxide, aluminum nitride, and any combination thereof. In some embodiments, the dielectric layer 108 is formed of multiple dielectric layers. For example, in some embodiments, the dielectric layer 108 includes a first dielectric layer formed on the charge trapping layer 106 and a second dielectric layer bonded to the first dielectric layer, where the second dielectric layer is formed on a donor wafer from which the device layer 110 is transferred. The dielectric layer 108 has any suitable thickness to enable the dielectric layer 108 to function as described. The thickness of the dielectric layer 108 may vary depending on the intended application of the multilayer structure 100. In various embodiments, the dielectric layer 108 has a thickness between 10 nm to 10 μm, such as between 10 nm to 1 μm.

In some embodiments, the charge trapping layer 106 is included. Where included, the charge trapping layer 106 is formed on the handle substrate 102 (e.g., by chemical vapor deposition) and positioned in the multilayer structure 100 between the handle substrate 102 and the dielectric layer 108. The charge trapping layer 106 includes a semiconductor material, such as a polycrystalline or amorphous semiconductor material. The semiconductor material included in the charge trapping layer 106 is suitably capable of forming a highly defective layer between the handle substrate 102 and the dielectric layer 108. In some embodiments, the charge trapping layer 106 includes polycrystalline or amorphous silicon, silicon germanium, silicon carbide, carbon-doped silicon, germanium, and combinations thereof. The term “polycrystalline” denotes a semiconductor material comprising small semiconductor crystals having random crystal orientations. For example, polycrystalline silicon grains may be as small in size as about 20 nanometers. Smaller crystal grain sizes of polycrystalline semiconductor material may provide higher defectivity in the charge trapping layer 106. The term “amorphous” denotes a semiconductor material that is in non-crystalline allotropic form, which lacks short range and long range order. Silicon grains having crystallinity over no more than about 10 nanometers may also be considered essentially amorphous silicon. The semiconductor material of the charge trapping layer 106 acts as a high density trap region to prevent and/or kill conductivity in the handle substrate 102 that may otherwise occur at an interface between the handle substrate 102 and the dielectric layer 108. The charge trapping layer 106 also prevents the formation of induced charge inversion or accumulation layers in the multilayer structure 100 that can contribute to power loss and non-linear behavior in electronic devices designed for radiofrequency (RF) device operation. The charge trapping layer 106 has any suitable thickness to enable the charge trapping layer to function as described. The thickness of the charge trapping layer 106 may vary depending on the intended application of the multilayer structure 100. In various embodiments, the charge trapping layer 106 has a thickness between 0.1 μm to 50 μm, such as between 1 μm to 10 μm.

The charge trapping layer 106 can be omitted in some embodiments.

The device layer 110 is the portion of the multilayer structure 100 upon or in which microelectronic devices are formed. In particular, the device layer 110 has an exposed or outer surface 112 that defines a top surface of the multilayer structure 100 upon or in which microelectronic devices are formed. In some embodiments, the device layer 110 includes single crystal silicon material, and the multilayer structure 100 is a silicon-on-insulator (SOI) structure having the silicon device layer 110. Thus, the multilayer structure 100 may interchangeably be referred to herein as an SOI structure 100. Although the device layer 110 is described as a silicon layer, the device layer 110 may additionally and/or alternatively include other semiconductor layers or multiple layers including, for example and without limitation, one or more layers of silicon, germanium, gallium arsenide, aluminum nitride, silicon germanium, gallium nitride, and combinations thereof. The device layer 110 has any suitable thickness to enable the device layer to function as described. The thickness of the device layer 110 may vary depending on the intended application of the multilayer structure 100. In various embodiments, the device layer 110 has a thickness between 10 nm to 3 μm, such as between 10 nm to 1 μm, or between 100 nm to 1 μm.

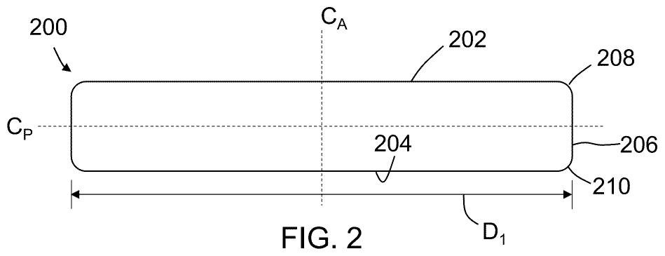

FIG. 2 depicts a single crystal semiconductor substrate 200, also referred to as a substrate 200, that is used in methods of preparing a multilayer structure 100 (FIG. 1) in accordance with embodiments of the present disclosure. In some embodiments, the substrate 200 is used as a semiconductor handle substrate, e.g., a single crystal semiconductor handle wafer. In some embodiments, the substrate 200 may also be used as a semiconductor donor substrate, e.g., a single crystal semiconductor donor wafer, in preparing the multilayer structure 100. As the description proceeds, the terms “substrate” and “wafer” are used interchangeably.

The substrate 200 includes two major, generally parallel surfaces 202, 204. One of the surfaces is a front surface 202 of the substrate 200, and the other surface is a back surface 204 of the substrate 200. The substrate 200 also includes a circumferential edge 206 joining the front surface 202 and the back surface 204. In some embodiments, the substrate 200 includes a beveled peripheral edge 208 extending between the front surface 202 and the circumferential edge 206 and/or a beveled peripheral edge 210 extending between the back surface 204 and the circumferential edge 206. The beveled peripheral edges 208, 210 are shown as being rounded in shape in the illustrated embodiment, but include other shapes in other embodiments (e.g., a chamfer). The beveled peripheral edges 208, 210 are contoured regions (e.g., rounded or chamfered) between the front and back surfaces 202, 204 of the substrate 200 and the circumferential edge 206.

The substrate 200 includes a central plane C_{P} between the front surface 202 and the back surface 204 and an imaginary central axis C_{A} substantially perpendicular to the central plane C_{P}. A radial length of the substrate 200 is measured as the distance between the central axis C_{A} and the circumferential edge 206. A diameter, D₁, of the substrate 200 is measured across the circumferential edge 206. The diameter D₁ varies depending on the intended application of the substrate 200. The diameter D₁ is between 150 millimeters (mm) to 450 mm in various embodiments. In some embodiments, the diameter D₁ is at least 150 mm, at least 200 mm, at least 300 mm, or at least 450 mm. In some embodiments, the diameter D₁ is about 150 mm, about 200 mm, about 300 mm, or about 450 mm.

Prior to any operation as described herein, the front surface 202 and the back surface 204 of the substrate 200 may be substantially identical. The surfaces 202 and 204 are referred to as a “front surface” or a “back surface,” respectively, for convenience and to distinguish the surface upon which subsequent process operations are performed. In the context of the present disclosure, the front surface 202 of the substrate 200 refers to the major surface of the substrate 200 that becomes an interior surface of a semiconductor-on-insulator structure 100 (FIG. 1). In accordance with embodiments described herein, it is with this front surface 202 that the intermediate layer 104 is in interfacial contact. The back surface 204 of the substrate 200 refers to the major surface that is exterior to the stacked succession of layers forming the semiconductor-on-insulator structure 100.

The substrate 200 includes a single crystal semiconductor material suitable for use in semiconductor-on-insulator applications. For example, in various embodiments, the substrate 200 includes a single crystal semiconductor material selected from the group consisting of silicon, germanium, silicon carbide, silicon germanium, gallium arsenide, other alloys of Group III and Group V elements, such as gallium nitride or indium phosphide, alloys of Group II and Group VI elements, such as cadmium sulfide or zinc oxide, and combinations thereof. In some embodiments, the substrate 200 includes a single crystal semiconductor material selected from the group consisting of silicon, silicon carbide, silicon germanium, gallium arsenide, gallium nitride, indium phosphide, indium gallium arsenide, germanium, and combinations thereof. In certain embodiments, the substrate 200 includes single crystal silicon.

As described above, the substrate 200 has a diameter D₁ that is, for example, between 150 mm to 450 mm, such as 150 mm or at least 150 mm, 200 mm or at least 200 mm, 300 mm or at least 300 mm, or 450 mm or at least 450 mm. A thickness of the substrate 200, measured between the front and back surfaces 202, 204, varies depending on the intended application of the substrate 200. In various embodiments, the thickness of the substrate is between 250 micrometers (μm) to 1500 μm, such as between 300 μm to 1000 μm, or between 500 μm to 1000 μm. In some specific embodiments, the thickness of the substrate 200 is about 775 μm.

In certain embodiments, the substrate 200 is a single crystal silicon wafer which has been sliced from a single crystal ingot grown in accordance with Czochralski crystal growing methods or float zone growing methods. Such methods, as well as silicon slicing, lapping, etching, and polishing techniques for preparing wafers from the ingots, are disclosed, for example, in F. Shimura, Semiconductor Silicon Crystal Technology, Academic Press, 1989, and Silicon Chemical Etching, (J. Grabmaier ed.) Springer-Verlag, N.Y., 1982, the entire disclosure of which is incorporated by reference herein. Suitably, the wafers are polished and cleaned by methods known to those skilled in the art. See, for example, W. C. O'Mara et al., Handbook of Semiconductor Silicon Technology, Noyes Publications.

The substrate 200 has interstitial oxygen in any suitable concentration that is generally achieved by the CZ or float zone growing methods. For example, the handle substrate may have an interstitial oxygen concentration of between 1×10¹⁶ atoms/cm³ to 5×10¹⁸ atoms/cm³. Interstitial oxygen concentration may be measured according to SEMI MF 1188-1105.

The substrate 200 has any resistivity obtainable by the CZ or float zone methods. The resistivity of the substrate 200 may vary based on the requirements of the end use/application of the semiconductor-on-insulator structure 100. The resistivity may vary from milliohm or less to megaohm or more. “High resistivity” substrates 200 have a minimum bulk resistivity of at least 500 Ohm-cm, such as between 500 Ohm-cm to 100,000 Ohm-cm. “Low resistivity” substrates 200 have a minimum bulk resistivity of below (less than or equal to) 500 Ohm-cm, such as between 1 Ohm-cm to 100 Ohm-cm. Methods for preparing wafers of varying resistivities are known in the art, and wafers having a desired resistivity may be obtained from commercial suppliers, such as GlobalWafers Co., Ltd., Taiwan.

In some embodiments, the substrate 200 has a relatively high minimum bulk resistivity. High resistivity single crystal semiconductor substrates 200 are generally sliced from single crystal ingots grown by the Czochralski method or float zone method, and may be subjected to a thermal anneal at a temperature ranging from 600° C. to 1000° C. in order to annihilate thermal donors caused by oxygen that are incorporated during crystal growth. In some embodiments, the substrate 200 has a minimum bulk resistivity of at least 500 Ohm-cm, at least 1000 Ohm-cm, or at least 3000 Ohm-cm, such as between 500 Ohm-cm and 100,000 Ohm-cm. Methods for preparing high resistivity wafers are known in the art, and such high resistivity wafers may be obtained from commercial suppliers, such as GlobalWafers Co., Ltd., Taiwan.

In some embodiments, the substrate 200 includes a p-type or an n-type dopant. Suitable p-type dopants include boron, gallium, or combinations thereof. Suitable n-type dopants include phosphorus, antimony, arsenic, or combinations thereof. The dopant concentration in the substrate 200 may be selected based on the desired resistivity of the handle substrate. In some embodiments, the substrate 200 is undoped.

In some embodiments, the substrate 200 is cleaned using an aqueous solution including an oxidizing agent, such as an SC1 and/or an SC2 cleaning solution. One example of a SC1 solution includes 5 parts deioinized water, 1 part aqueous NH₄OH (ammonium hydroxide, 29% by weight of NH₃), and 1 part of aqueous H₂O₂ (hydrogen peroxide, 30%). Such SC1 solutions may also include cyclohexanediaminetetraacetic acid (CDTA), for example, at a concentration of about 690 ppm in the NH₄OH solution. SC1 solutions may also be used in chemical mechanical polishing (“CMP”) operations, described below, for example, at a concentration about 1/7 of 690 ppm, or approximately 100 ppm. One example of a SC2 solution comprises 5 parts deioinized water, 1 part aqueous HCl (hydrochloric acid, 39% by weight), and 1 part of aqueous H₂O₂ (hydrogen peroxide, 30%). Additionally, a chelating agent (e.g., cyclohexanediaminetetraacetic acid (CDTA)) may be employed in the cleaning solutions and processes disclosed herein, including, for example and without limitation, the clean-and-etch operations described herein, SC1 cleaning solutions used for post CMP cleans (e.g., at a ratio of 1:1:5 or a concentration of approximately 100 ppm), and post edge polish cleaning baths (e.g., SC1). Additional examples and details of using chelating agents in an SC1 solution are described, for example, in U.S. Pat. No. 5,962,384, the entire contents of which are incorporated herein by reference.

In some embodiments, the front surface 202 of the substrate 200 is subjected to a chemical mechanical polishing (“CMP”) operation. A suitable CMP operation involves the immersion of the substrate 200 in an abrasive slurry and polishing the front surface 202 of the substrate 200 using a polymeric pad, whereby through a combination of chemical and mechanical work the front surface 202 is smoothed to a desired surface roughness. One example of a slurry that is used in the CMP operation contains abrasive particles and a chemical etchant is applied to the polishing pad. As an example, the CMP operation removes less than 1 μm (e.g., about 0.4 μm) of material from the front surface 202 of the substrate 200. In some embodiments, the CMP operation includes removal of fine or “micro” scratches caused by large size colloidal silica, such as Syton® from DuPont Air Products Nanomaterials, LLC, in the polishing slurry to produce a highly reflective, damage-free front surface 202 of the substrate 200. As an example, the CMP operation includes an intermediate polishing operation and a finishing polishing operation, and the intermediate and finishing polishing steps may be performed using the same polishing machine or separate machines. One example of a finish polishing slurry includes an ammonia base and a reduced concentration of colloidal silica. During the finish polishing, the finish polishing slurry is injected between the polishing pad and the front surface 202 of the substrate 200 and the polishing pad works the finish polishing slurry against the front surface 202 to remove any remaining scratches and haze so that the front surface 202 is highly-reflective and damage free.

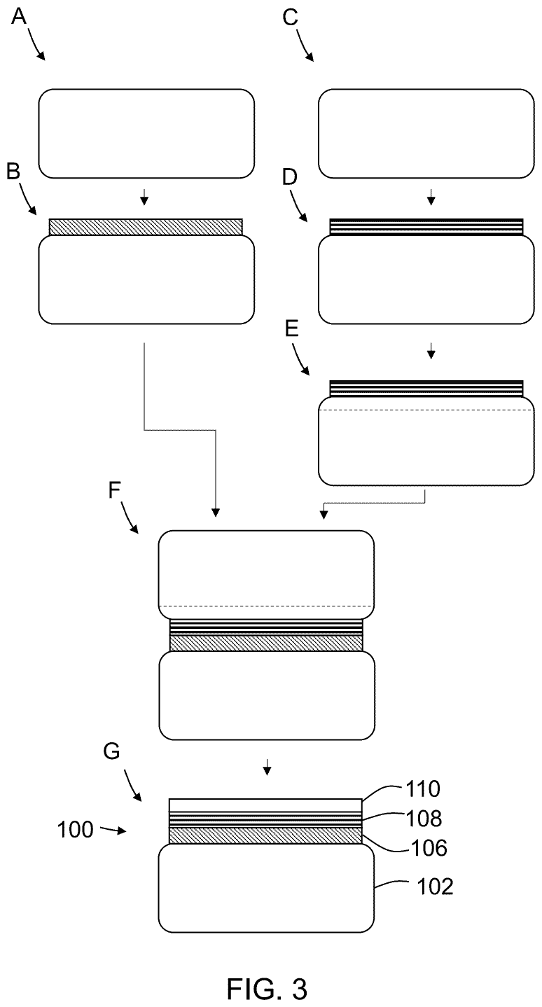

FIG. 3 is an example process flow of forming the SOI structure 100 of FIG. 1. The process begins at steps A, where a handle substrate is provided, and step C, where a donor substrate is provided. Each of the handle substrate and the donor substrate may include the substrate 200 of FIG. 1. In various embodiments, the handle substrate (step A) and the donor substrate (step C) are independently made of single crystal silicon, or other suitable semiconductor materials, such as germanium, silicon carbide, silicon germanium, gallium arsenide, and other alloys of Group III and Group V elements, such as gallium nitride or indium phosphide, or alloys of Group II and Group VI elements, such as cadmium sulfide or zinc oxide. In some embodiments, the handle substrate and the donor substrate independently include a single crystal semiconductor material selected from the group consisting of silicon, silicon carbide, silicon germanium, gallium arsenide, gallium nitride, indium phosphide, indium gallium arsenide, germanium, and combinations thereof. In certain embodiments, each of the handle substrate and the donor substrate includes single crystal silicon.

At least a portion of the intermediate layer 104 can be grown on one or both of the handle substrate (step B of FIG. 3) or the donor substrate (step D of FIG. 3). In this example, at step B, the charge trapping layer 106 is grown on the handle substrate using a suitable deposition process (e.g., metalorganic chemical vapor deposition (MOCVD), physical vapor deposition (PVD), chemical vapor deposition (CVD), plasma enhanced chemical vapor deposition (PECVD), low pressure chemical vapor deposition (LPCVD), or molecular beam epitaxy (MBE)). At step D, the dielectric layer 108 is grown on the donor substrate by thermal oxidation, CVD oxide deposition, or another suitable technique to grow the dielectric layer 108, such as an oxide film. In some embodiments, the donor substrate is thermally oxidized in a furnace such as an ASM A400 or an ASM A412 to grow the dielectric layer 108. In some embodiments, the dielectric layer 108 is additionally or alternatively grown on the handle substrate. In some embodiments, a dielectric layer 108 is grown on each of the donor substrate and the handle substrate. The dielectric layer 108 may be grown on the charge trapping layer 106. In some embodiments, the charge trapping layer 106 is omitted. In such embodiments, the dielectric layer 108 may be grown on the handle substrate or no portion of the intermediate layer 104 may be grown on the handle substrate. The intermediate layer 104 may be entirely grown on the donor substrate or entirely grown on the handle substrate.

Still referring to FIG. 3, the semiconductor device layer 110 in the SOI structure 100 shown in FIG. 1 is derived from the donor substrate. The donor substrate is bonded to the handle substrate, with the intermediate layer 104 positioned between the bonded substrates, and a portion of the donor substrate is removed from the bonded structure to thereby transfer the device layer 110 and the dielectric layer 108 onto the handle substrate 102 and form the SOI structure 100. The device layer 110 and dielectric layer 108 may be transferred onto the handle structure by wafer thinning techniques such as etching the donor substrate or by cleaving the donor substrate at a cleave plane (formed at step E).

In the example process of FIG. 3, at step E, a cleave plane is formed in the donor substrate by particle or ion implantation techniques. Particle or ion implantation is suitably carried out in a commercially available instrument, such as an Applied Materials Quantum H. Implanted particles or ions include He, H, H₂, or combinations thereof. Particles or ion implantation is carried out at a density and duration sufficient to form the cleave plane in the donor substrate. Implant density may range from 10¹² ions/cm² to 10¹⁷ ions/cm², such as from 10¹⁴ ions/cm² to 10¹⁷ ions/cm². Implant energies may range from 1 keV to 3,000 keV, such as from 5 keV to 3,000 keV. The depth of implantation determines, at least in part, the thickness of the device layer 110 in the final SOI structure 100 (shown in FIG. 1). In some embodiments, ion implantation is performed after formation of the dielectric layer 108 on the front surface of the donor substrate. In some embodiments, the donor substrate is subjected to a cleaning operation after the implant. A suitable clean includes a Piranha clean followed by a deionized water rinse and/or cleaning using a SC1 and/or SC2 solution.

In some embodiments, the donor substrate having been subjected to helium ion and/or hydrogen ion implant is annealed at a temperature sufficient to form a thermally activated cleave plane in the donor substrate. An example of a suitable tool includes a Box furnace, such as a Blue M model. In some embodiments, the ion implanted donor substrate is annealed at a temperature of from 200° C. to 350° C. Thermal annealing may occur for a duration of from 2 hours to 10 hours. Thermal annealing within these temperatures ranges is sufficient to form a thermally activated cleave plane. After the thermal anneal to activate the cleave plane, the front surface and/or back surfaces of the donor substrate may be cleaned using cleaning operations described above.

In some embodiments, the bonding surfaces of the donor substrate and the handle substrate are activated prior to bonding (step F). In some embodiments, the oxygen plasma surface activation tool is a commercially available tool, such as those available from EV Group, such as EVG®810LT Low Temp Plasma Activation System. Oxygen plasma surface oxidation is performed in order to render a bonding surface of the donor substrate and/or the handle substrate hydrophilic and amenable to bonding.

Still referring to FIG. 3, at step F, the optionally plasma activated bonding surfaces of the donor substrate and the handle substrate are next brought into intimate contact to thereby form a bonded structure. In the illustrated embodiment, the bonded structure includes the dielectric layer, e.g., a buried oxide layer, of the donor substrate in interfacial contact with the charge trapping layer of the handle substrate. In other embodiments, two dielectric layers, one on each of the donor substrate and the handle substrate, may be in interfacial contact in the bonded structure. In other embodiments, a dielectric layer on one of the donor substrate and the handle substrate is in interfacial contact with the other one of the donor and handle substrate in the bonded structure. Since the mechanical bond between the handle substrate and the donor substrate may be relatively weak, the bonded structure can be further annealed to solidify the bond. In some embodiments, the bonded structure is annealed at a temperature sufficient to strengthen the bond and form a thermally activated cleave plane in the donor substrate. An example of a suitable tool might be a Box furnace, such as a Blue M model. In some embodiments, the bonded structure is annealed at a temperature of from 200° C. to 350° C. Thermal annealing may occur for a duration of from 0.5 hours to 10 hours.

After the bonding and, optionally, thermal anneal to strengthen the bond, the bonded structure is cleaved at step G in FIG. 3. The bonded structure is cleaved at the cleave plane to produce the final SOI structure 100 (shown in FIG. 1) that includes the handle substrate 102, the intermediate layer (here, the charge trapping layer 106 and the dielectric layer 108), and the device layer 110. Alternatively, a portion of the donor substrate may be removed using another suitable layer transfer or wafer thinning technique to form the final SOI structure 100, such as grinding or back-side etching.

Cleaving the bonded structure is performed according to techniques known in the art. In some embodiments, mechanical cleaving is used. In some embodiments, the bonded structure is placed in a conventional cleave station affixed to stationary suction cups on one side and affixed by additional suction cups on a hinged arm on the other side. A crack is initiated near the suction cup attachment and the movable arm pivots about the hinge cleaving the donor substrate apart at the cleave plane. Cleaving removes a portion of the donor substrate, thereby transferring the device layer 110 (e.g., a silicon device layer) on the SOI structure 100.

After transfer of the device layer 110 (e.g., by cleave), the SOI structure 100 may be subjected to post-layer transfer processing to smooth the outer surface 112 of the device layer 110. For example, after layer transfer, the SOI structure 100 may be subjected to a high temperature anneal, which may also strengthen the bonds between adjacent layers of the SOI structure 100. The high temperature anneal may be performed on multiple SOI structures 100 in a batch furnace to reduce costs, but may be performed on an individual SOI structure 100 in a single wafer processing chamber. An example of a suitable tool for the high temperature anneal is a vertical furnace, such as an ASM A400 or an ASM A412. The high temperature anneal is suitably performed at a temperature and for a duration sufficient to smooth a surface of the device layer 110 and/or strengthen the bonds between adjacent layers in the SOI structure 100. In some embodiments, the SOI structure 100 is annealed at a temperature of greater than or equal to 950° C., such as between 1000° C. to 1200° C., and for a duration of between 15 minutes to 10 hours. The high temperature anneal of the SOI structure 100 may, in some embodiments, be performed in the presence of an anneal atmosphere that includes at least one of an inert gas (e.g., argon gas), hydrogen (H₂) gas, and helium gas, or a combination of two or more of these gases. For example, the high temperature anneal may be performed at a temperature of between 1000° C. to 1200° C., for a duration of between 2 hours to 4 hours, in the presence of argon gas. The high temperature anneal may additionally and/or alternatively be performed in an “active” gas environment, for example, in the presence of nitrogen (N₂) gas, oxygen (O₂) gas, or a combination of N₂ and O₂ gas. A high temperature anneal in an active gas environment may be performed to strengthen the bonds between adjacent layers of the SOI structure 100, but typically will not smooth surfaces of the SOI structure 100 (e.g., the outer surface 112 of the device layer 110).

In some embodiments, the SOI structure 100 may be subjected to post-layer transfer smoothing operations in addition to or in the alternative to the high temperature anneal. For example, a polishing operation, such as CMP, may be performed on the SOI structure 100 to planarize one or both of the exposed surfaces of the SOI structure (e.g., the outer surface 112 of the transferred device layer 110). The polishing operation may be performed in addition to (e.g., before and/or after) or in the alternative to the high temperature thermal anneal. For example, a CMP operation may be performed on the transferred device layer 110, followed by the high temperature thermal anneal performed on the SOI structure 100. However, in some embodiments, a CMP operation is omitted.

Additionally or alternatively, the SOI structure 100 is subjected to a non-contact smoothing process, also referred to as epitaxial smoothing or “epi-smoothing,” after the high temperature anneal and/or the polishing operation. The epi-smoothing process may further reduce the roughness of the outer surface 112 of the device layer 110 on the SOI structure 100 and/or remove any implant damage of the device layer 110 that was not compensated for by any previous smoothing processes (e.g., in the high temperature thermal anneal and/or the polishing operation). Example epi-smoothing processes are described, for example, in U.S. Pat. No. 9,202,711, issued Dec. 1, 2015, the disclosure of which is hereby incorporated by reference herein in its entirety. The epi-smoothing process is typically performed in a suitable reactor (e.g., an epitaxial deposition reactor) that is operable to heat the SOI structure 100 in a reaction chamber and introduce etchant gases into the reaction chamber that perform work on (e.g., etch) the transferred device layer 110 to further smooth the outer surface 112. For example, the epi-smoothing process may include positioning the SOI structure 100 in an epi-reactor chamber, heating the chamber to a temperature between 900° C. and 1100° C., introducing gaseous etchant (e.g., hydrogen chloride, HCl, or chlorine and hydrogen gas, H₂) into the chamber, and maintaining temperature and flow of the gaseous etchant for a suitable duration to achieve a targeted surface roughness of the transferred device layer 110.

In accordance with methods of the present disclosure, following layer transfer of the device layer 110 and before any additional post-layer transfer smoothing operations performed on the SOI structure 100, a clean-and-etch operation is performed on the device layer to remove a damaged region at the outer surface of the device layer 110. The damaged region may include contaminants and particles that are attracted to broken bonds of the single crystal semiconductor material (e.g., single crystal silicon) that is included in the device layer 110. The damaged region is defined at an exposed surface of the device layer 110 opposite the intermediate layer 104. The damaged region includes single crystal semiconductor material of the device layer 110 and extends a thickness from the exposed surface. In some embodiments, the damaged region that is removed by the clean-and-etch operation has a thickness of at least 10 Angstroms, at least 30 Angstroms, at least 50 Angstroms, or at least 100 Angstroms, such as between 30 Angstroms to 300 Angstroms, between 30 Angstroms to 200 Angstroms, between 100 Angstroms to 200 Angstroms, or between 150 Angstroms to 200 Angstroms. With the clean-and-etch operation performed to remove the damaged region after cleave, no additional process may be needed between the clean and the thermal smoothing (thermal annealing or epi-smoothing) to achieve desired surface roughness of the device layer 110. That is, removal of the damaged region by the clean-and-etch operation facilitates reducing or eliminating the pit and bump defects in the device layer 110 following thermal smoothing that otherwise deteriorate the surface roughness of the device layer 110. In some embodiments, the clean-and-etch operation eliminates the need to perform any CMP operation on the device layer 110.

In the methods of the present disclosure, the clean-and-etch operation includes contacting the exposed surface of the single crystal semiconductor device layer with an alkaline solution at a temperature and for a duration sufficient to remove the damaged region. In some embodiments, the alkaline solution is an alkali-oxide including at least one oxidizing agent and at least one alkaline agent. In some embodiments, the at least one alkaline agent is selected from the group consisting of ammonium hydroxide (NH₄OH), other amines such as di-, tri-, and tetra-amines (e.g., tetramethylammonium hydroxide (TMAH)), alkali metal hydroxides (e.g., NaOH, KOH, LiOH, Ca(OH)₂, Mg(OH)₂), organic hydroxides, and inorganic hydroxides. In some embodiments, the at least one oxidizing agent is selected from the group consisting of hydrogen peroxide (H₂O₂), an aqueous ozone (O₃) solution, and a mixture of nitric acid (HNO₃), hydrogen chloride (HCl), and/or sulfuric acid (H₂SO₄). In such embodiments, the alkali-oxide includes the at least one alkaline agent, the at least one oxidizing agent, and deionized water in a concentration ratio (by volume) between 1:1:5 to 1:10:250, such as between 1:1:100 to 1:10:175, or 1:7:130 (alkaline agent:oxidizing agent:deionized water). In one example, the at least one oxidizing agent is UHP hydrogen peroxide (30-32 wt. %) and the at least one alkaline agent is UHP ammonium hydroxide (28-30 wt. %). In other embodiments, other hydroxides, such as NaOH, KOH, or other alkali or alkaline metal hydroxides, such as Ca(OH)₂ or Mg(OH)₂, may be used for an etching operation (e.g., as an alternative to the clean-and-etch operation), followed by a rinse and an SC1 cleaning operation. In any of the foregoing embodiments, the alkaline solutions may also employ chelating agents or reducing agents (e.g., H₂ bubbling, forming gas bubbling, dithionate, thiosulfate, etc.) to prevent or block metallic contamination and remove out-diffused metal contamination. In some embodiments, for example, the alkaline solution includes include cyclohexanediaminetetraacetic acid (CDTA). In one example, the alkaline solution includes CDTA at a concentration of about 5 ppm in an alkali-oxide that includes at least one alkaline agent, at least one oxidizing agent, and deionized water in a concentration ratio (by volume) of about 1:7:130 (alkaline agent:oxidizing agent:deionized water).

In some embodiments, the clean-and-etch operation includes contacting the exposed surface of the single crystal semiconductor device layer with the alkaline solution at a temperature of at least 40° C., or at least 55° C., or at least 65° C., such as between 55° C. to 85° C., between 65° C. to 85° C., between 70° C. to 80° C., or about 75° C. At such temperatures, the clean-and-etch operation includes contacting the exposed surface of the single crystal semiconductor device layer with the alkaline solution at the temperature and for a duration of less than two hours, such as between five minutes to two hours, between 5 minutes to one hour, or between 5 minutes to 50 minutes. Suitably, the temperature and the duration may be finely tuned to remove the desired thickness of the damaged region without introducing an excessive amount of metal impurities that cannot be removed using SC2 cleaning.

In some embodiments, the clean-and-etch operation further includes oxidizing the exposed surface of the single crystal semiconductor device layer prior to contacting the exposed surface with the alkaline solution. For example, oxidizing the exposed surface can include contacting the exposed surface with an aqueous ozone (O₃) solution. In these embodiments, the aqueous ozone solution can include ozone in a concentration of between 0.1 parts per million by weight (ppmw) to 90 ppmw, such as between 15 ppmw to 90 ppmw, or about 20 ppmw. Oxidizing the exposed surface can be performed for a duration of at least 10 seconds, such as between 10 seconds to one hour, between 1 minute to 10 minutes, or about two minutes.

In some embodiments, the clean-and-etch operation further includes contacting the exposed surface of the single crystal semiconductor device layer with an aqueous solution configured to remove surface metals from the exposed surface after contacting the exposed surface with the alkaline solution and removing the damaged region. For example, the clean-and-etch operations includes an SC2 clean after removing the damaged portion. In these embodiments, the aqueous solution configured to remove surface metals from the exposed surface suitably does not substantially remove any of the single crystal semiconductor material from the single crystal semiconductor device layer.

The aqueous solution configured to remove surface metals from the exposed surface can be one of an acid-oxide solution or carbon dioxide dissolved in deionized water. For example, the aqueous solution configured to remove surface metals from the exposed surface is an acid-oxide solution including deionized water, at least one acid, and at least one oxidizing agent. The at least one acid can be selected from the group consisting of hydrogen chloride (HCl) and hydrogen fluoride (HF). The at least one oxidizing agent can be selected from the group consisting of hydrogen peroxide (H₂O₂) and an aqueous ozone (O₃) solution. In some embodiments, the aqueous solution configured to remove surface metals from the exposed surface includes the at least one acid, the at least one oxidizing agent, and deionized water in a concentration ratio (by volume) between 1:0:50 to 1:5:250, such as between 1:0:75 to 1:4:150, or 1:0:100 (acid:oxidizing agent:deionized water). In one example, the at least one oxidizing agent is UHP hydrogen peroxide (30-32 wt. %) and the at least one acid is UHP hydrogen chloride (35-37 wt. %).

In some embodiments, the clean-and-etch operation includes contacting the exposed surface of the single crystal semiconductor device layer with the aqueous solution configured to remove surface metals from the exposed surface at a temperature of at least 40° C., or at least 55° C., such as between 40° C. to 80° C., between 55° C. to 65° C., or about 60° C. In such embodiments, the clean-and-etch operation includes contacting the exposed surface of the single crystal semiconductor device layer with the aqueous solution configured to remove surface metals from the exposed surface at the temperature and for a duration of less than five minutes, such as between thirty seconds to five minutes, between one minute to two minutes, or about 90 seconds.

In some embodiments, contacting the exposed surface of the single crystal semiconductor device layer with the alkaline solution is performed in an agitating bath. This may facilitate removal of the damaged region. The agitating bath can include, for example and without limitation, megasonic waves and/or mechanical agitation of the device layer in a cleaning tank.

Following the clean-and-etch operation and thermal smoothing, the device layer 110 has a suitable thickness for device fabrication. The SOI structure 100 may subsequently be subjected to further processing based on an intended application or use of the SOI structure. For example, an epitaxial layer may be deposited on the outer surface 112 of the transferred device layer 110. An epitaxial layer deposited on the device layer 110 may include substantially the same electrical characteristics as the underlying device layer. Alternatively, the epitaxial layer deposited on the device layer 110 may include different electrical characteristics as the underlying device layer. An epitaxial layer may comprise a material selected from the group consisting of silicon, silicon carbide, silicon germanium, gallium arsenide, gallium nitride, indium phosphide, indium gallium arsenide, germanium, and combinations thereof. In embodiments where epi-smoothing is performed on the SOI structure 100, the SOI structure may remain in the reactor and be subjected to an epi-deposition process in the same reactor, or the epitaxial layer may be deposited on the device layer 110 in a separate reactor. Depending upon the desired properties of the final device, the epitaxial layer may comprise a dopant, such as one or more p-type dopants (e.g., boron, gallium, aluminum, and/or indium) and/or one or more n-type dopants (e.g., phosphorus, antimony, and/or arsenic). The final SOI structure 100 may additionally and/or alternatively be subjected to end of line metrology inspections and cleaned a final time using typical SC1-SC2 process. Oxidation may further be performed on one or more exposed surfaces of the SOI structure 100 for reducing bow or warp of the structure 100.

### Examples

The following non-limiting examples further illustrate the subject matter of the present disclosure.

Examples of a clean-and-etch operation consist of three chemistry cleaning baths with high-purity DI water rinses between each of the cleaning baths and an ultra-clean, drying process. Such a clean-and-etch operation can be used to remove damaged surface regions on a top semiconductor device layer (e.g., top silicon layer) of an SOI structure. The damaged region may have a thickness of at least 10 Angstroms, at least 30 Angstroms, at least 50 Angstroms, or at least 100 Angstroms, such as between 30 Angstroms to 300 Angstroms, between 30 Angstroms to 200 Angstroms, between 100 Angstroms to 200 Angstroms, or between 150 Angstroms to 200 Angstroms. Depending on the thickness of the damaged region, the process conditions (e.g., duration) may be tuned.

The first of the three chemistries is a wet-oxidation process. The second cleaning chemistry is an alkaline (pH>7) cleaning process with megasonic agitation and bulk agitation. Due to the pH being greater than 7 in the presence of hydrogen peroxide, some etching removal of the top device layer (e.g., top silicon layer) is observed, as well as a change in the surface roughness of the top device layer. The final cleaning process is an acidic (pH<7) cleaning process for surface metal removal.

Operable ranges for examples of a clean-and-etch process in accordance with the present disclosure are shown in Table 1 below.

TABLE 1
Clean-and-etch Concentrations, Temperatures, and Times

| Attribute | Range |
|---|---|
| 1. O₃ conc. (ppmw) | 0.1-90 (e.g., 15-90, or 20) |
| 2. O₃ clean time (sec.) | 10-3600 (e.g., 60-600, or 120 |
| 3. Clean-and-etch temperature (° C.) | 40° C.-boiling (e.g., 65-85° C., or 75° C.) |
| 4. Clean-and-etch conc. (vol.:vol.:vol.)^{†} | 1:1:5-1:10:250 (e.g., 1:1:100-1:10:175, or 1:7:130) |
| 5. Clean-and-etch time (sec.) | 300-7200 (e.g., 300-3600, or 300-3000) |
| 6. SC-2 temperature (° C.) | 40-80 (e.g., 55-65 or 60) |
| 7. SC-2 conc. (vol.:vol.:vol.)^{‡} | 1:0:50-1:5:250 (e.g., 1:0:75-1:4:150, or 1:0:100) |
| 8. SC-2 time (sec.) | 30-300 (e.g., 60-120, or 90) |

^{†}Volumes (ratios) of conc. UHP NH₄OH (28-30 wt. %): conc. UHP H₂O₂ (30-32 wt %): UHP DIW.
^{‡}Volumes (ratios) of conc. UHP HCl (35-37 wt %): conc. UHP H₂O₂ (30-32 wt %): UHP DIW.
Time dependent upon SC1 chemistry, concentration, temperature, to achieve target surface characteristics (sub-surface damage, particles, surface metal contamination, etc.).

The cleaning chemistries given in the table are provided by way of example only. In some embodiments, the clean-and-etch operation leverages cleaning chemistries used in the semiconductor industry under the mixed constraints of throughput, capital cost, cost of ownership, particle removal/cleaning efficiency, consumables cost, ease of use, operator interface, safety considerations, environmental waste management, etc. However, alternative chemistries with similar function can be substituted with no effect on the overall utility and performance of the process, provided a high-temperature clean-and-etch using a SC1-type (alkaline-peroxide-etching) cleaning step is used in the sequence. Preferably, this alkaline peroxide etch cleaning step is done at reasonable concentration and adequate agitation to provide uniform access and to eliminate bubble masking effects (J. Electrochem. Soc. 147 176, 2000), which will tend to only promote surface roughening.

For example, the oxidation cleaning bath can be, instead of O₃ dissolved in UHP DIW, piranha/sulfuric-peroxide mixture (SPM) (hot, 120° C., or higher, H₂SO₄+H₂O₂, e.g. 9:1 conc. stock solutions) or other oxidizing (low pH preferred), e.g., acids. A higher temperature (acid) oxidizing bath may also be effective at removing some fast diffuser metals, such as Copper. Further, a mixture of HNO₃ and HCl may be used in replacement of dissolved O₃. Alkaline peroxide with a high concentration of hydrogen peroxide will promote oxidation in the first cleaning bath without the etching effect (and thus function as a non-etching oxidizing bath). Hydrofluoric acid mixtures are less preferred, as these would tend to leave the surface free of a (chemical) oxide.

For example, the clean-and-etch bath may be composed of an alkali chemical other than NH₄OH (e.g. TMAH, NaOH, KOH, organic-based (amine) hydroxides, inorganic hydroxides, etc.) and an oxidizing chemical compatible with aqueous alkali solution (i.e. non-acidic, e.g. peroxide, O₃ DIW, etc.). TMAH or alkali metals may provide an advantage over conventional SC1 in terms of pH (OH⁻ conc.) since many of these chemicals are less volatile compared to ammonium hydroxide, and less alkali chemical would thus be lost to exhaust and composition control would be more robust and easier to manage.

As a further example, the SC2 bath may be composed of dilute (e.g. 500 ppm) HF and dissolved O₃ (e.g., 10 to 20 ppm) or dilute HF and H₂O₂, or CO₂ dissolved in UHP DIW. This bath is tailored to remove any surface metals from the preceding chemical and rinse baths, prior to the final rinse bath and dry. This bath would not affect the top semiconductor or silicon layer characteristics (e.g., sub-surface damage, particles, metal contaminants, etc.). In comparison, HF-based cleaning would be less desirable for SOI wafers which have specified thickness oxide on the backside or terrace region, as the oxide thickness may be reduced.

Also, surface active agents (surfactants) (e.g. IPA for SC2 or dHF, for example) which are compatible with the chemistry and alter the surface tension (or surface energy) may be strategically employed. And (metal) chelating agents (e.g. CDTA, EDTA, etc. for SC1 chemistry) compatible with the chemistry of the cleaning bath may be employed. Additionally or alternatively, dissolved gases, such as COₓ, may chelate metals or alter the surface energy or enhance cavitation in sonic-agitated cleaning baths. The pH and addition of hydroxide ions of the SC1 cleaning bath may also be altered using ammonia gas, rather than ammonium hydroxide.

Any of the above-described and following modifications (assuming they are congruent with the process) may be employed without detracting from the scope of this disclosure: alkaline etch-cleaning with agitation to produce a top semiconductor or silicon surface with desirable surface characteristics prior to further thermal processing (low surface roughness, low sub-surface damage, low metals).

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” “front,” back,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method of preparing a semiconductor-on-insulator structure from a bonded structure including a single crystal semiconductor handle substrate, a single crystal semiconductor donor substrate, and a dielectric layer positioned between the handle substrate and the donor substrate, the single crystal semiconductor donor substrate including a cleave plane, the method comprising:
cleaving the bonded structure at the cleave plane to remove a portion of the single crystal semiconductor donor substrate from the bonded structure, thereby forming a cleaved structure comprising the single crystal semiconductor handle substrate, the dielectric layer, and a single crystal semiconductor device layer, wherein the single crystal semiconductor device layer defines a damaged region at an exposed surface opposite the dielectric layer, wherein the damaged region includes single crystal semiconductor material and extends a thickness from the exposed surface;
removing the damaged region from the single crystal semiconductor device layer of the cleaved structure using a clean-and-etch operation that includes contacting the exposed surface of the single crystal semiconductor device layer with an alkaline solution at a temperature and for a duration sufficient to remove the damaged region; and
smoothing the single crystal semiconductor device layer with the damaged region removed.

2. The method of claim 1, wherein the alkaline solution is an alkali-oxide including at least one oxidizing agent and at least one alkaline agent.

3. The method of claim 2, wherein the at least one alkaline agent is selected from the group consisting of ammonium hydroxide (NH₄OH), tetramethylammonium hydroxide (TMAH), alkali metal hydroxides, organic hydroxides, and inorganic hydroxides.

4. The method of claim 2, wherein the at least one oxidizing agent is selected from the group consisting of hydrogen peroxide (H₂O₂) and an aqueous ozone (O₃) solution.

5. The method of claim 2, wherein the alkali-oxide includes the at least one alkaline agent, the at least one oxidizing agent, and deionized water in a concentration ratio by volume between 1:1:5 to 1:10:250 (alkaline agent:oxidizing agent:deionized water).

6. The method of claim 5, wherein the at least one oxidizing agent is UHP hydrogen peroxide (30-32 wt. %) and the at least one alkaline agent is UHP ammonium hydroxide (28-30 wt. %).

7. The method of claim 1, wherein the clean-and-etch operation includes contacting the exposed surface of the single crystal semiconductor device layer with the alkaline solution at a temperature of at least 40° C.

8. The method of claim 7, wherein the clean-and-etch operation includes contacting the exposed surface of the single crystal semiconductor device layer with the alkaline solution at the temperature and for a duration of less than two hours.

9. The method of claim 8, wherein the duration is between five minutes to two hours.

10. The method of claim 1, wherein the clean-and-etch operation further includes oxidizing the exposed surface of the single crystal semiconductor device layer prior to contacting the exposed surface with the alkaline solution.

11. The method of claim 10, wherein oxidizing the exposed surface includes contacting the exposed surface with an aqueous ozone (O₃) solution.

12. The method of claim 11, wherein the aqueous ozone solution includes ozone in a concentration of between 0.1 parts per million by weight (ppmw) to 90 ppmw.

13. The method of claim 10, wherein oxidizing the exposed surface is performed for a duration of at least 10 seconds.

14. The method of claim 1, wherein the clean-and-etch operation further includes contacting the exposed surface of the single crystal semiconductor device layer with an aqueous solution configured to remove surface metals from the exposed surface after contacting the exposed surface with the alkaline solution and removing the damaged region.

15. The method of claim 14, wherein the aqueous solution configured to remove surface metals from the exposed surface does not substantially remove any of the single crystal semiconductor material from the single crystal semiconductor device layer.

16. The method of claim 14, wherein the aqueous solution configured to remove surface metals from the exposed surface is one of an acid-oxide solution or carbon dioxide dissolved in deionized water.

17. The method of claim 16, wherein the aqueous solution configured to remove surface metals from the exposed surface is an acid-oxide solution including deionized water, at least one acid, and at least one oxidizing agent.

18. The method of claim 17, wherein the at least one acid is selected from the group consisting of hydrogen chloride (HCl) and hydrogen fluoride (HF).

19. The method of claim 17, wherein the at least one oxidizing agent is selected from the group consisting of hydrogen peroxide (H₂O₂) and an aqueous ozone (O₃) solution.

20. The method of claim 17, wherein the aqueous solution configured to remove surface metals from the exposed surface includes the at least one acid, the at least one oxidizing agent, and deionized water in a concentration ratio by volume between 1:0:50 to 1:5:250.

21. The method of claim 20, wherein the at least one oxidizing agent is UHP hydrogen peroxide (30-32 wt. %) and the at least one acid is UHP hydrogen chloride (35-37 wt. %).

22. The method of claim 14, wherein the clean-and-etch operation includes contacting the exposed surface of the single crystal semiconductor device layer with the aqueous solution configured to remove surface metals from the exposed surface at a temperature of at least 40° C.

23. The method of claim 22, wherein the clean-and-etch operation includes contacting the exposed surface of the single crystal semiconductor device layer with the aqueous solution configured to remove surface metals from the exposed surface at the temperature and for a duration of less than five minutes.

24. The method of claim 23, wherein the duration is between thirty seconds to five minutes.

25. The method of claim 1, wherein contacting the exposed surface of the single crystal semiconductor device layer with the alkaline solution is performed in an agitating bath.

26. The method of claim 1, wherein the damaged region has a thickness of at least 10 Angstroms.

27. The method of claim 26, wherein the damaged region has the thickness of between 30 Angstroms to 300 Angstroms.

28. The method of claim 1, wherein the single crystal semiconductor donor substrate is a single crystal silicon wafer.

29. The method of claim 1, wherein the cleave plane is formed in the single crystal semiconductor donor substrate by implanting particles into the donor substrate.

30. The method of claim 1, wherein cleaving the bonded structure at the cleave plane comprises mechanical cleaving.

31. The method claim 1, wherein smoothing the single crystal semiconductor device layer includes at least one of thermal annealing and epitaxial smoothing.

32. The method of claim 31, wherein no additional smoothing operation is performed on the single crystal semiconductor device layer.
